(19) United States
(12) Patent Application Publication
(10) Pub. No.: US 2025/0061039 A1
(43) Pub. Date: Feb. 20, 2025

(54) HUMAN FACTOR ASSESSMENT METHOD AND SYSTEM FOR AUTONOMOUS DRIVING

(71) Applicant: ELECTRONICS AND TELECOMMUNICATIONS RESEARCH INSTITUTE, Daejeon (KR)

(72) Inventors: Woo Jin KIM, Daejeon (KR); Do Wook KANG, Daejeon (KR); Jung Sook KIM, Daejeon (KR); Dae Sub YOON, Daejeon (KR); Mi CHANG, Daejeon (KR); Eun Hye JANG, Daejeon (KR)

(21) Appl. No.: 18/800,295

(22) Filed: Aug. 12, 2024

(30) Foreign Application Priority Data
Aug. 14, 2023 (KR) 10-2023-0106165
Jul. 30, 2024 (KR) 10-2024-0100878

(51) Int. Cl. G06F 11/34

(52) U.S. Cl. CPC G06F 11/3457

(57) ABSTRACT

The present invention relates to a human factor assessment method and system for autonomous driving. The human factor assessment method of autonomous driving includes generating an autonomous driving system twin based on autonomous driving system specifications and autonomous driving service logic, generating one or more human twins based on a human twin characteristic range, performing a simulation using the autonomous driving system twin and the human twin, and calculating a performance index of the autonomous driving service based on the simulation result.

### CROSS-REFERENCE TO RELATED APPLICATIONS

This application claims priority under 35 U.S.C. § 119 to Korean Patent Applications No. 10-2023-0106165, filed on Aug. 14, 2023, and No. 10-2024-0100878, filed on Jul. 30, 2024, in the Korean Intellectual Property Office, the disclosure of which are incorporated herein by reference in its entirety.

### BACKGROUND

### 1. Field of the Invention

The present invention relates to a method and system for assessing performance indexes of functions equipped in an autonomous driving vehicle, and more particularly, to a method and system for assessing performance indexes of technical functions of various services provided by an autonomous driving vehicle.

The present invention was carried out with the support of the Ministry of Trade, Industry and Energy/Korea Planning & Evaluation Institute of Industrial Technology (KEIT) (No. 20018248, Development of Safety of the intended functionality from insufficiency of perception and decision making).

### 2. Description of Related Art

Mobility services using autonomous driving vehicles are continuously being developed, and their forms and functions are expected to become more diverse in the future. Safety and convenience are important for autonomous driving mobility services. However, when new assessment criteria and technologies for safety and convenience are not secured, expanding the market of the autonomous driving mobility services may become difficult or more likely to fail. In particular, as the randomness of driver behavior increases due to the development of autonomous driving technology, the importance of driver human factors is increasing, and thus the demand for assessment of interaction between autonomous driving vehicles and drivers is steadily increasing.

After the Tesla accident in March 2018, the National Transportation Safety Board (NTSB) of the United States conducted an investigation for about two years and announced safety recommendations including driver status monitoring technology in February 2020. Most of the content of the safety recommendations was content related to driver human factors. In addition, standards such as ISO 23793 and 21448 were established in relation to driver human factors of autonomous driving vehicles, and safety standards such as UNECEWP.29 also encourage driver monitoring and safety assessment accordingly. In addition, driver human factors are reflected in assessment items of the Euro New Car Assessment Programme (Euro NCAP), and global safety guidelines related to human factors are being strengthened.

Until now, safety and usability have been assessed by a method of allowing an actual driver to drive an autonomous driving vehicle according to a given scenario based on a vehicle simulator and deriving and analyzing a human factor based on the data collected at that time. However, the existing method of employing an actual driver and analyzing limited scenarios is expected to have difficulty handling the increasing demand for autonomous driving mobility services, such as advanced driver assistance system (ADAS), in-vehicle infotainment (IVI), and connectivity, that will be diversified in the future. Instead of employing an actual driver, the development of a massive and intensive human twin software-based assessment technology is urgent.

The existing performance indexes and assessment methods of an autonomous driving vehicle are present, but the assessments related to human factors that reflect various characteristics and environmental changes of drivers/passengers rely on analyzing limited scenarios by employing an actual driver. Accordingly, the existing performance indexes and assessment methods are very time-consuming and costly, and can handle only limited driving situations. Therefore, the existing assessment methods have limitations in verifying autonomous driving human factors for various subjects (elderly/disabled/ordinary people). These limitations are because the existing assessment methods rely on a method in which people directly use autonomous driving services. Therefore, in order to overcome these limitations, the development of performance index assessment technology for digital human twin-based autonomous driving services is required.

### SUMMARY OF THE INVENTION

The present invention provides a human factor assessment method and system for autonomous driving capable of performing performance index assessment of autonomous driving service logic in advance through human-system linkage simulation by calling a digital human twin and an autonomous driving system twin before launching an autonomous driving vehicle-related service.

Aspects of the present invention are not limited to the above-described aspect. That is, other aspects that are not mentioned may be obviously understood by those skilled in the art from the following specification.

According to an embodiment of the present invention, a human factor assessment method of autonomous driving includes: receiving, by a human factor assessment system for autonomous driving, a human twin characteristic range, autonomous driving system specifications, autonomous driving service logic, and a target task; generating, by the human factor assessment system for autonomous driving, an autonomous driving system twin model based on the autonomous driving system specifications, the autonomous driving service logic, and the target task; generating, by the human factor assessment system for autonomous driving, a human twin model based on the human twin characteristic range and the target task; and generating, by the human factor assessment system for autonomous driving, a state information history by performing a simulation on an autonomous driving service under preset simulation conditions using the autonomous driving system twin model and the human twin model.

The human factor assessment method of autonomous driving may further include calculating, by the human factor assessment system for autonomous driving, a performance index on the autonomous driving service based on the state information history.

The human factor assessment method of autonomous driving may further include determining, by the human factor assessment system for autonomous driving, whether the performance index meets a predetermined reference value, and changing the autonomous driving service logic when the performance index does not meet the predetermined reference value.

The human twin model may include a cognitive model and a behavioral model.

The cognitive model may be a cognitive architecture-based cognitive model.

According to another embodiment of the present invention, a human factor assessment system for autonomous driving includes: an input interface device; a memory configured to store computer-readable instructions; and at least one processor configured to execute the instructions.

The input interface device may receive a human twin characteristic range, autonomous driving system specifications, autonomous driving service logic, and a target task.

The at least one processor may be configured to execute the instructions to generate an autonomous driving system twin model based on the autonomous driving system specifications, the autonomous driving service logic, and the target task, generate a human twin model based on the human twin characteristic range and the target task, and perform a simulation on an autonomous driving service under preset simulation conditions using the autonomous driving system twin model and the human twin model to generate a state information history.

The at least one processor may be configured to calculate a performance index for the autonomous driving service based on the state information history.

The at least one processor may be configured to determine whether the performance index meets a predetermined reference value, and when the performance index does not meet the predetermined reference value, change the autonomous driving service logic.

The human twin model may include a cognitive model and a behavioral model.

The cognitive model may be a cognitive architecture-based cognitive model.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating a configuration of a human factor assessment system for autonomous driving according to an embodiment of the present invention.

FIG. 2 is a flowchart for describing a human factor assessment method of autonomous driving according to an embodiment of the present invention.

FIG. 3 is a block diagram illustrating a computer system for implementing a human factor assessment method of autonomous driving according to an embodiment of the present invention.

### DETAILED DESCRIPTION OF EXEMPLARY EMBODIMENTS

Advantages and features of the present invention and methods to achieve them will be elucidated from exemplary embodiments described below in detail with reference to the accompanying drawings. However, the present invention is not limited to embodiments disclosed below, and may be implemented in various different forms, these embodiments will be provided only in order to make the present invention complete and allow one of ordinary skill in the art to which the present invention pertains to completely recognize the scope of the present invention, and the present invention will be defined by the scope of the claims. Meanwhile, terms used in the present specification are for explaining exemplary embodiments rather than limiting the present invention. Unless explicitly described to the contrary, a singular form includes a plural form in the present specification. The terms “comprise” and/or “comprising” as used herein do not exclude the existence or addition of one or more other components, steps, operations, and/or elements in addition to the mentioned components, steps, operations, and/or elements.

Terms such as “first” and “second” may be used to describe various components, but these components are not to be interpreted as limited by these terms. These terms may be used to differentiate one component from other components. For example, a “first” component may be named a “second” component and a “second” component may also be similarly named a “first” component, without departing from the scope of the present invention.

It is to be understood that when one component is referred to as being “connected to” or “coupled to” another component, the one component may be connected directly to or coupled directly to the other component or be connected to or coupled to the other component with another component interposed therebetween. On the other hand, it is to be understood that when one component is referred to as being “connected directly to” or “coupled directly to” another component, it may be connected to or coupled to the other component with no other component interposed therebetween. Other expressions describing a relationship between components, such as “between,” “directly between,” “neighboring,” “directly neighboring,” and the like, are to be similarly interpreted.

In the present invention, an autonomous driving service is a service provided by a system equipped in an autonomous driving system or an autonomous driving vehicle. For example, the autonomous driving service may be driver monitoring, control right transition of an autonomous driving vehicle, etc. Specifically, the autonomous driving service has the form of autonomous driving service logic, and is implemented by performing simulations by setting parameters of an autonomous driving system twin model.

When it is decided that the detailed description of the known art related to the present invention may unnecessarily obscure the gist of the present invention, the detailed description will be omitted.

Hereinafter, embodiments of the present invention will be described in detail with reference to the accompanying drawings. The same means will be denoted by the same reference numerals throughout the accompanying drawings in order to facilitate the general understanding of the present invention in describing the present invention.

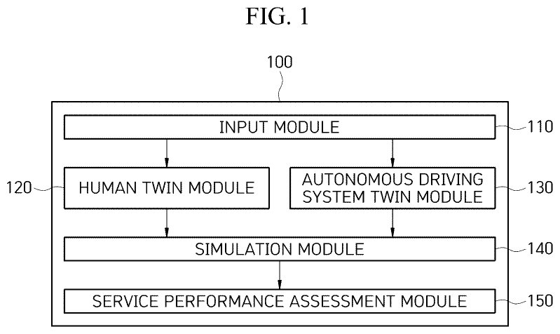

FIG. 1 is a block diagram illustrating a configuration of a human factor assessment system for autonomous driving according to an embodiment of the present invention.

Referring to FIG. 1, a human factor assessment system 100 for autonomous driving according to an embodiment of the present invention is configured to include an input module 110, a human twin module 120, an autonomous driving system twin module 130, a simulation module 140, and a service performance assessment module 150. The human factor assessment system 100 for autonomous driving illustrated in FIG. 1 is according to an embodiment, and the components of the human factor assessment system 100 for autonomous driving according to the present invention are not limited to the embodiment illustrated in FIG. 1, and may be added, changed, or deleted if necessary.

The input module 110 receives a characteristic range of a human twin (hereinafter, “human twin characteristic range”), autonomous driving system specifications, autonomous driving service logic, and a target task from a user or an external system.

The human twin is a digital twin that simulates a user (end user) who interacts with an autonomous driving system twin on the human factor assessment system 100 for autonomous driving. The user may be a driver or a user of the autonomous driving vehicle, or a pedestrian. The human twin is a digital twin that performs cognition and behavior while interacting with an autonomous driving system twin during a simulation process of performing a target task for assessing an autonomous driving service. In the present invention, the human twin is implemented as a human twin model, and the human twin model includes a cognitive model and a behavioral model. The human twin model may be implemented based on deep learning.

The human twin characteristic range is the range of characteristics that the human twin has. For example, the characteristics of the human twin may include demographic information such as age, gender, and driving experience. However, the present invention does not limit the characteristics of the human twin to the examples described above. That is, information other than the demographic information described above may be included in the characteristics of the human twin. For example, appearance information such as a length of hair may be included in the characteristics of the human twin, and when the autonomous driving service is a driver monitoring service, the appearance information is a variable that may affect a performance index of the driver monitoring service. Specifically, when the length of the hair becomes longer, the accuracy of a driver status may decrease depending on a location of a camera for driver monitoring. This is because a driver's face may be largely covered by the hair.

The autonomous driving system twin is a digital twin that simulates an autonomous driving system or an autonomous driving vehicle. In the present invention, the autonomous driving system twin is implemented as an autonomous driving system twin model.

The autonomous driving system specifications may include a size, weight, acceleration, installed sensors, autonomous driving level, etc., of the autonomous driving vehicle equipped with the autonomous driving system to be tested. The autonomous driving system specifications may be parameters of the autonomous driving system twin model.

The autonomous driving service logic is logic to be equipped in the autonomous driving system and is a verification target of the human factor assessment system 100 for autonomous driving. For example, the autonomous driving service logic may include lane keeping logic, automatic lane change logic, etc. The autonomous driving service logic may be a parameter of the autonomous driving system twin model.

The target task is a task given to assess the performance index of the autonomous driving service, and is a behavioral goal of the human twin and/or an operation goal of the autonomous driving system twin.

For example, when the autonomous driving service to be assessed is the driver monitoring service and the performance index of the autonomous driving service is the detection accuracy for a passenger's state (e.g., an alert state, a drowsy state), the behavioral goal of the human twin, i.e., the target task, may enter a drowsy state at a specific time or condition.

As another example, when the autonomous driving service being assessed is a control right transition of the autonomous driving vehicle, the performance index of the autonomous driving service may be a control right transition time or a safety index (e.g., a degree of rapid acceleration, rapid deceleration, and rapid steering of a vehicle at the time of control right transition). In this case, the behavioral goal of the human twin may be drinking water at the time of an error in the sensor equipped in the autonomous driving vehicle, and the operation goal of the autonomous driving system twin may make a determination on the control right transition based on the sensor and driver monitoring results.

As another example, when the autonomous driving service to be assessed is an in-vehicle infotainment service, the performance index of the autonomous driving service may be an operating time or the number of operations of a user when using a specific infotainment service. In this case, the behavioral goal of the human twin may be finding and playing a specific movie using the infotainment service.

The input module 110 transmits the already input human twin characteristic range and target task to the human twin module 120. Then, the input module 110 transmits the already input autonomous driving system specifications, autonomous driving service logic, and target task to the autonomous driving system twin module 130.

The human twin module 120 generates the human twin based on the human twin characteristic range. Specifically, in the present invention, generating the human twin means determining the parameters of the human twin model. The human twin model may be an artificial neural network-based model, and is a model that simulates a person riding in the autonomous driving vehicle (or using the autonomous driving system) or a pedestrian.

The human twin module 120 determines the characteristics of the human twin through random selection from the given human twin characteristic range, and determines the values of the parameters that set the human twin model based on the determined characteristics. For example, the parameters of the human twin model include the appearance, joint structure, cognitive reaction time, and behavioral goal of the human twin. In this case, the human twin module 120 determines the age, gender, and driving experience of the human twin through the random selection from the human twin characteristic range. In addition, the human twin module 120 may determine the appearance and joint structure (e.g., upper limb skeleton) of the human twin based on the age and gender of the human twin, and determine the cognitive reaction time of the human twin through a table or a pre-trained deep learning model based on the age and driving experience of the human twin. In addition, the human twin module 120 sets the determined appearance and cognitive reaction time of the human twin and the behavioral goal of the human twin extracted from the target task as the parameters of the human twin model.

The human twin model includes a cognitive model and a behavioral model. The cognitive model is a model that simulates the cognitive process of the human twin, and the behavioral model is a model that simulates the behavioral process of the human twin. The cognitive model may include a cognitive architecture-based cognitive model and/or a multimodal artificial intelligence model that simulates perception functions. For example, the cognitive model may be a model built using general-purpose cognitive architecture such as adaptive control of thought-rational (ACT-R) or Soar, a general cognitive architecture.

The cognitive model receives simulation conditions (e.g., an in-cabin scene, weather, road information), autonomous driving system twin information (e.g., vehicle behavior information, human-machine interface (HMI) provision information) generated by the autonomous driving system twin mode, and behavioral information (e.g., a posture vector of the human twin) generated by the behavioral model to generate cognitive information. The cognitive information may include perception results (e.g., visual/auditory/tactile information), memory content, and decision-making (e.g., a next behavior) of the human twin.

In addition, the behavioral model is a model that generates a behavior trajectory according to human body control logic. For example, the behavioral model may be a deep learning model trained by a reinforcement learning method, a biomechanics-based model that reflects a human body's movement mechanism, or a physics engine-based model (e.g., unity, unreal engine). The behavioral model may be composed of an ensemble of the deep learning model, the biomechanics-based model, and the physics engine-based model.

The behavioral model receives the information (e.g., target position) inferred by the human twin module 120 from the simulation conditions, the cognitive information generated by the cognitive model, the joint structure of the human twin, and the behavioral goal of the human twin to generate the behavioral information. The behavioral information may include a behavioral trajectory (time series posture vector), a joint torque, and a force used for interaction with a peripheral interface (HMI), etc.

The human twin module 120 transmits the generated human twin model to the simulation module 140.

The autonomous driving system twin module 130 generates the autonomous driving system twin based on the autonomous driving system specifications, the autonomous driving service logic, and the target task received from the input module 110. Specifically, in the present invention, generating the autonomous driving system twin means determining the parameters of the autonomous driving system twin model. The autonomous driving system twin model is a model that simulates an autonomous driving system (or an autonomous driving vehicle) and may be an artificial neural network-based model.

The autonomous driving system twin module 130 determines the parameters of the autonomous driving system twin model based on the autonomous driving system specifications or values processed from the autonomous driving system specifications, the autonomous driving service logic, and the target task (operation goal of the autonomous driving system twin). The autonomous driving system twin model may include a vehicle dynamics model, a vehicle-mounted sensor data generation model, an actuator data generation model, an in-vehicle interface model, and an autonomous driving service logic processing model.

The autonomous driving system twin model receives the simulation conditions and the information generated by the human twin model to generate the autonomous driving system twin information. The autonomous driving system twin information may include information such as the behavior, trajectory, and mode of the vehicle.

The autonomous driving system twin module 130 transmits the autonomous driving system twin model to the simulation module 140.

The simulation module 140 generates a state information history by performing the simulation using the human twin model and the autonomous driving system twin model based on the input from the user or the external device or the preset simulation conditions (e.g., an in-cabin scene, weather, road information, driving patterns of nearby vehicles, movement of pedestrians, locations of driver monitoring cameras, an infotainment interface, etc.). The simulation is for assessing the autonomous driving services (or autonomous driving service logic). The state information history is a dataset of all time series data generated by the human twin model and the autonomous driving system twin model during the simulation process. For example, the state information history may be a dataset that synthesizes the time series data such as the perception results of the human twin, the joint torque, the posture vector, the operation information of the infotainment interface, the driver status (alertness, drowsiness), and the driver monitoring results.

The simulation module 140 transmits the generated state information history to the service performance assessment module 150.

The service performance assessment module 150 calculates the performance index of the autonomous driving service based on the state information history. The performance index may be a safety index or a usability index.

For example, the service performance assessment module 150 may calculate the detection accuracy of the driver status based on time series data on the driver status and the driver monitoring results. The detection accuracy of the driver status corresponds to the safety index.

As another example, the service performance assessment module 150 may calculate the number of operations based on the time series data on the operation information of the infotainment interface of the human twin. The number of operations corresponds to the usability index.

The service performance assessment module 150 determines whether the calculated performance index meets criteria. When the performance index of the autonomous driving service does not meet the criteria, the service performance assessment module 150 may transmit it to the user of the human factor assessment system 100 for autonomous driving through the output interface to modify the autonomous driving service logic, and may transmit a message that the performance index does not meet the criteria to the autonomous driving system twin module 130 so that the autonomous driving system twin module 130 may select different logic from among the pre-stored autonomous driving service logics. When the user modifies the autonomous driving service logic or the autonomous driving system twin module 130 selects different autonomous driving service logic, the parameters of the autonomous driving system twin model may change and thus the simulation may be performed again.

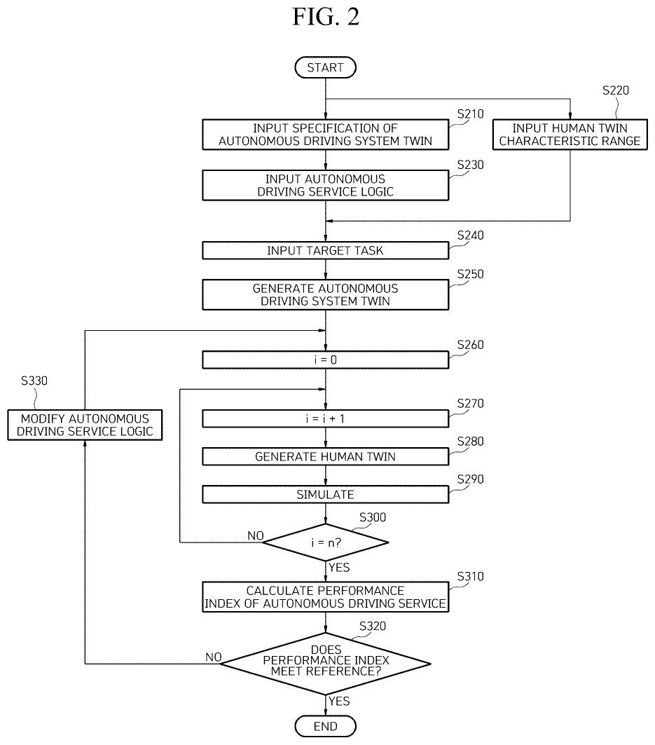

FIG. 2 is a flowchart for describing a human factor assessment method of autonomous driving according to an embodiment of the present invention. The human factor assessment system 100 for autonomous driving supports the development of autonomous driving services suitable for various human characteristics according to the flowchart of the embodiment of FIG. 2. Referring to FIG. 2, the human factor assessment method of autonomous driving according to an embodiment of the present invention includes operations S210 to S330. The human factor assessment method of autonomous driving illustrated in FIG. 2 is according to an embodiment, and the operations of the human factor assessment method of autonomous driving according to the present invention are not limited to the embodiment illustrated in FIG. 2, and may be added, changed, or deleted if necessary. Operation S210 is an operation of inputting specifications of an autonomous driving system.

The input module 110 receives the specifications of the autonomous driving system from the user or the external system and transmits the received specifications to the autonomous driving system twin module 130. The autonomous driving system specifications may include a size, weight, acceleration, installed sensors, autonomous driving level, etc., of the autonomous driving vehicle equipped with the autonomous driving system to be tested.

Operation S220 is an operation of inputting autonomous driving service logic.

The input module 110 receives the autonomous driving system logic from the user or the external system and transmits the received autonomous driving system logic to the autonomous driving system twin module 130. The autonomous driving service logic is logic to be equipped in the autonomous driving system and is a verification target of the human factor assessment system 100 for autonomous driving. Examples of the autonomous driving service logic may include lane maintenance logic, automatic lane change logic, driver monitoring logic, infotainment system operation logic, etc.

Operation S230 is an operation of receiving the input of the human twin characteristic range.

The input module 110 receives the human twin characteristic range from the user or the external system and transmits the received human twin characteristic range to the human twin module 120. For example, the characteristics of the human twin may include demographic information such as age, gender, and driving experience. Operation S240 is an operation of receiving the input of the target task.

The input module 110 receives the target task from the user or the external system and transmits the received target task to the human twin module 120 and the autonomous driving system twin module 130. The target task is a task given to assess the performance index of the autonomous driving service, and is a behavioral goal of the human twin and/or an operation goal of the autonomous driving system twin.

Operation S250 is an operation of generating the autonomous driving system twin.

The autonomous driving system twin module 130 generates the autonomous driving system twin based on the autonomous driving system specifications, the autonomous driving service logic, and the target task received from the input module 110. Specifically, in the present invention, generating the autonomous driving system twin (or autonomous driving system twin model) means determining the values of parameters of the autonomous driving system twin model.

The autonomous driving system twin module 130 transmits the autonomous driving system twin model whose parameter values have been determined to the simulation module 140.

Operation S260 is an operation of initializing a simulation execution index.

In this operation, the simulation module 140 initializes a simulation execution index i to 0. The simulation execution index i is an index used to repeat the simulation as many times as the number n of set human twins.

Operation S270 is an operation of increasing the simulation execution index by 1.

In this operation, the simulation module 140 increases the simulation execution index i by 1.

Operation S280 is an operation of generating the human twin.

The human twin module 120 generates the human twin based on the human twin characteristic range. Specifically, in the present invention, generating the human twin (or human twin model) means determining the parameters of the human twin model. The human twin model may be an artificial neural network-based model, and is a model that simulates a person riding in the autonomous driving vehicle (or using the autonomous driving system) or a pedestrian.

The human twin module 120 determines the characteristics of the human twin through random selection from the given human twin characteristic range, and determines the values of the parameters that set the human twin model based on the determined characteristics.

The human twin module 120 transmits the human twin model whose parameter values are determined to the simulation module 140.

Operation S290 is a simulation operation.

The simulation module 140 generates a state information history by performing the simulation using the human twin model and the autonomous driving system twin model based on the input from the user or the external device or the preset simulation conditions (e.g., an in-cabin scene, weather, road information, driving patterns of nearby vehicles, movement of pedestrians, locations of driver monitoring cameras, an infotainment interface, etc.). The simulation is for assessing the autonomous driving services (or autonomous driving service logic). The state information history is a dataset of all time series data generated by the human twin model and the autonomous driving system twin model during the simulation process. For example, the state information history may be a dataset that synthesizes the time series data such as the perception results of the human twin, the joint torque, the posture vector, the operation information of the infotainment interface, the driver status (alertness, drowsiness), and the driver monitoring results. The simulation module 140 transmits the state information history to the service performance assessment module 150.

Operation S300 is an operation of determining whether the simulation execution index has reached the set upper limit. In this operation, the simulation module 140 determines whether the simulation execution index i has reached the preset upper limit, i.e., the number n of human twins to be tested. The human factor assessment system 100 for autonomous driving proceeds with operation S310 when the simulation execution index i has reached the upper limit n, and if not, proceeds with operation S270 to repeat the generation of the human twin model and the simulation.

Operation S310 is an operation of calculating the performance index of the autonomous driving service.

The service performance assessment module 150 calculates the performance index of the autonomous driving service based on the status information history.

For example, the service performance assessment module 150 may calculate the detection accuracy of the driver status based on the time series data for the driver status and the driver monitoring results for each human twin, and calculate the average or dispersion of the detection accuracy for all the human twins to calculate the comprehensive performance index for the autonomous driving service.

Operation S320 is an operation of determining whether the performance index meets the criteria. The service performance assessment module 150 determines whether each performance index or the comprehensive performance index is greater than or equal to a predetermined reference value (threshold value).

When the performance index is greater than or equal to the criteria, the human factor assessment system 100 for autonomous driving terminates the process, and otherwise, receives the modified autonomous driving service logic from the user or the external system through the input module 110 or goes through the process in which the autonomous driving system twin module 130 selects different logic from among a plurality of autonomous driving service logics that have been previously input (S330), and then performs the simulation on n human twins again.

The above human factor assessment method of autonomous driving has been described with reference to the flowchart illustrated in the drawing. For simplicity, the method has been illustrated and described as a series of blocks, but the invention is not limited to the order of the blocks, and some blocks may occur with other blocks in a different order from that illustrated and described in the present specification or at the same time. Also, various other branches, flow paths, and orders of blocks that achieve the same or similar results may be implemented. In addition, all the illustrated blocks may be not required for implementation of the methods described in the present specification.

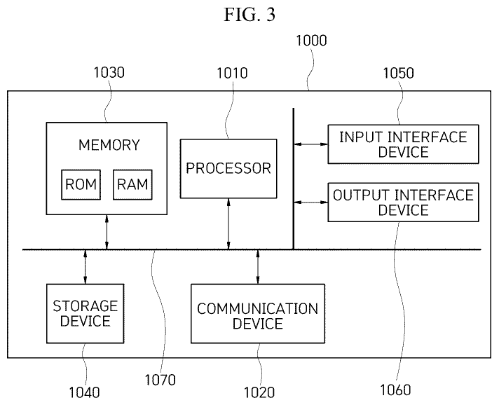

FIG. 3 is a block diagram illustrating a computer system for implementing a human factor assessment method of autonomous driving according to an embodiment of the present invention. The human factor assessment system 100 for autonomous driving may be implemented in the form of the computer system illustrated in FIG. 3.

Referring to FIG. 3, a computer system 1000 may include at least one of a processor 1010, a memory 1030, an input interface device 1050, an output interface device 1060, and a storage device 1040 that communicate with each other through a bus 1070. The computer system 1000 may further include a communication device 1020 coupled to a network. The processor 1010 may be a central processing unit (CPU) or a semiconductor device that executes instructions stored in the memory 1030 or the storage device 1040. The memory 1030 and the storage device 1040 may include various types of volatile or non-volatile storage media. For example, the memory 1030 may include a read only memory (ROM) and a random access memory (RAM). In the embodiment of the present invention, the memory 1030 may be located inside or outside the processing unit, and the memory 1030 may be connected to the processing unit through various known means. The memory 1030 may be various types of volatile or non-volatile storage media, and may include, for example, a ROM or a RAM.

Accordingly, the embodiment of the present invention may be implemented as a computer-implemented method, or as a non-transitory computer-readable medium having computer-executable instructions stored thereon. In an embodiment, when executed by the processing unit, the computer-readable instructions may perform the method according to at least one aspect of the present invention.

In addition, the method according to the embodiment of the present invention may be implemented in the form of program instructions that may be executed through various computer means and may be recorded in a computer-readable recording medium.

The computer-readable recording medium may include program commands, data files, data structures, or the like, alone or in combination. The program instructions recorded in the computer-readable recording medium may be configured by being especially designed for the embodiment of the present invention, or techniques known to those skilled in the field of computer software may be used. The computer-readable recording medium may include a hardware device configured to store and execute the program instructions. Examples of the computer-readable recording medium may include a magnetic medium such as a hard disk, a floppy disk, and a magnetic tape, an optical medium such as a CD-ROM or a DVD, a magneto-optical medium such as a floptical disk, a ROM, a RAM, a flash memory, or the like. Examples of the program instructions may include a high-level language code capable of being executed by a computer using an interpreter, or the like, as well as a machine language code made by a compiler.

The processor 1010 may perform the computer-readable instructions stored in the memory 1030 to perform the functions of the human twin module 120, the autonomous driving system twin module 130, the simulation module 140, and the service performance assessment module 150 described above in FIGS. 1 and 2.

The communication device 1020 may transmit or receive a wired signal or a wireless signal.

The input interface device 1050 may perform the function of the input module 110 described above. The input interface device 1050 transmits the received data and information to the processor 1010.

For reference, the components according to the embodiment of the present invention may be implemented in the form of software or hardware such as a digital signal processor (DSP), a field programmable gate array (FPGA), or an application specific integrated circuit (ASIC), and perform predetermined roles.

However, “components” are not limited to software or hardware, and each component may be configured to be in an addressable storage medium or to reproduce one or more processors.

Accordingly, for example, the components include components such as software components, object-oriented software components, class components, and task components, processors, functions, attributes, procedures, subroutines, segments of a program code, drivers, firmware, microcode, circuits, data, databases, data structures, tables, arrays, and variables.

Components and functions provided within the components may be combined into a smaller number of components or further divided into additional components.

Meanwhile, it will be appreciated that each block of a processing flowchart and combinations of the flowcharts may be executed by computer program instructions. Since these computer program instructions may be mounted in a processor of a general computer, a special computer, or other programmable data processing devices, these computer program instructions executed through the processor of the computer or the other programmable data processing devices create means performing functions described in a block(s) of the flowchart. Since the computer program instructions may also be mounted on the computer or the other programmable data processing devices, the instructions performing a series of operation steps on the computer or the other programmable data processing devices to create processes executed by the computer, thereby executing the computer or the other programmable data processing devices may also provide steps for performing the functions described in a block(s) of the flowchart.

In addition, each block may indicate some of modules, segments, or codes including one or more executable instructions for executing a specific logical function (specific logical functions). Further, it is to be noted that functions mentioned in the blocks may occur out of sequence in some alternative embodiments. For example, two blocks that are continuously illustrated may in fact be simultaneously performed or performed in a reverse sequence depending on corresponding functions.

The term “module” used in the present embodiments refers to a software component or a hardware component such as FPGA or ASIC, and a “module” performs certain roles. However, a “module” is not meant to be limited to software or hardware. A “module” may be configured to be stored in a storage medium that can be addressed or may be configured to regenerate one or more processors. Accordingly, as an example, “module” refers to components such as software components, object-oriented software components, class components, and task components, processes, functions, attributes, procedures, subroutines, segments of program code, drivers, firmware, microcode, circuits, data, databases, data structures, tables, arrays and variables. Components and functions provided within “modules” may be combined into a smaller number of components and “modules” or may be further separated into additional components and “modules.” In addition, components and “modules” may be implemented to play one or more CPUs in a device or a secure multimedia card.

In the past, a person would directly ride in an autonomous driving vehicle or sit in a simulator similar to an autonomous driving vehicle and drive according to a set scenario, and data would be collected using sensors, thereby assessing the safety and usability of autonomous driving services.

According to the present invention, it is possible to call the digital human twin of a person with various characteristics without a person riding directly and assess the safety and usability of the autonomous driving service in advance through the linked simulation. According to the present invention, since the assessment is performed in advance using the digital twin technology, it is possible to obtain the experimental results for people with more diverse characteristics than the existing method, and since the simulations for various scenarios are possible, it is possible to reduce the time and cost of producing a prototype.

In addition, the existing autonomous driving service market had a problem in that it was difficult to select the business model or enter the market due to high time consumption/costs, which resulted in a high unit price and put a high burden on the end user. However, according to the present invention, since the time and cost required for assessment may be reduced, it is possible to lower the price of the product and reduce the burden on the end user.

Effects which can be achieved by the present invention are not limited to the above-described effects. That is, other objects that are not described may be obviously understood by those skilled in the art to which the present invention pertains from the following description.

Although exemplary embodiments of the present invention have been disclosed above, it may be understood by those skilled in the art that the present invention may be variously modified and changed without departing from the scope and spirit of the present invention described in the following claims.

What is claimed is:

1. A human factor assessment method of autonomous driving, comprising:
receiving, by a human factor assessment system for autonomous driving, a human twin characteristic range, autonomous driving system specifications, autonomous driving service logic, and a target task;
generating, by the human factor assessment system for autonomous driving, an autonomous driving system twin model based on the autonomous driving system specifications, the autonomous driving service logic, and the target task;
generating, by the human factor assessment system for autonomous driving, a human twin model based on the human twin characteristic range and the target task; and
generating, by the human factor assessment system for autonomous driving, a state information history by performing a simulation on an autonomous driving service under preset simulation conditions using the autonomous driving system twin model and the human twin model.

2. The human factor assessment method of claim 1, further comprising calculating, by the human factor assessment system for autonomous driving, a performance index on the autonomous driving service based on the state information history.

3. The human factor assessment method of claim 2, further comprising determining, by the human factor assessment system for autonomous driving, whether the performance index meets a predetermined reference value, and changing the autonomous driving service logic when the performance index does not meet the predetermined reference value.

4. The human factor assessment method of claim 1, wherein the human twin model includes a cognitive model and a behavioral model.

5. The human factor assessment method of claim 4, wherein the cognitive model is a cognitive architecture-based cognitive model.

6. A human factor assessment system for autonomous driving, comprising:
an input interface device;
a memory configured to store computer-readable instructions; and
at least one processor configured to execute the instructions,
wherein the input interface device receives a human twin characteristic range, autonomous driving system specifications, autonomous driving service logic, and a target task, and
the at least one processor is configured to execute the instructions to generate an autonomous driving system twin model based on the autonomous driving system specifications, the autonomous driving service logic, and the target task,
generate a human twin model based on the human twin characteristic range and the target task, and
perform a simulation on an autonomous driving service under preset simulation conditions using the autonomous driving system twin model and the human twin model to generate a state information history.

7. The human factor assessment system of claim 6, wherein the at least one processor is configured to calculate a performance index for the autonomous driving service based on the state information history.

8. The human factor assessment system of claim 7, wherein the at least one processor is configured to determine whether the performance index meets a predetermined reference value, and when the performance index does not meet the predetermined reference value, change the autonomous driving service logic.

9. The human factor assessment system of claim 6, wherein the human twin model includes a cognitive model and a behavioral model.

10. The human factor assessment system of claim 9, wherein the cognitive model is a cognitive architecture-based cognitive model.
